(19) United States
(12) Patent Application Publication
(10) Pub. No.: US 2017/0345834 A1
(43) Pub. Date: Nov. 30, 2017

(54) SOI MEMORY DEVICE

(71) Applicant: GLOBALFOUNDRIES Inc., Grand Cayman (KY)

(72) Inventor: Thomas Melde, Dresden (DE)

(21) Appl. No.: 15/163,785

(22) Filed: May 25, 2016

(51) Int. Cl. H01L 27/11524; H01L 29/06; H01L 21/28; H01L 27/1157; H01L 29/788; H01L 29/66

(52) U.S. Cl. CPC H01L 27/11524; H01L 29/788; H01L 29/66833; H01L 29/66825; H01L 21/28273; H01L 27/1157; H01L 21/28282; H01L 29/0649

(57) ABSTRACT

A method of manufacturing a semiconductor device is provided including providing a silicon-on-insulator substrate comprising a semiconductor bulk substrate, a buried oxide layer formed on the semiconductor bulk substrate and a semiconductor layer formed on the buried oxide layer, and forming a memory device on the SOI substrate including forming a floating gate from a part of the semiconductor layer, forming an insulating layer on the floating gate, and forming a control gate on the insulating layer.

### BACKGROUND OF THE INVENTION

### 1. Field of the Invention

Generally, the present disclosure relates to the field of integrated circuits and semiconductor devices and, more particularly, to the manufacture of SOI flash memory devices.

### 2. Description of the Related Art

The fabrication of advanced integrated circuits, such as CPUs, storage devices, application specific integrated circuits (ASICs) and the like, requires the formation of a large number of circuit elements on a given chip area according to a specified circuit layout. In a wide variety of electronic circuits, field effect transistors represent one important type of circuit element that substantially determines performance of the integrated circuits. Generally, a plurality of process technologies are currently practiced for forming field effect transistors (FETs), wherein, for many types of complex circuitry, MOS technology is currently one of the most promising approaches due to the superior characteristics in view of operating speed and/or power consumption and/or cost efficiency. During the fabrication of complex integrated circuits using, for instance, CMOS technology, millions of N-channel transistors and P-channel transistors are formed on a substrate including a crystalline semiconductor layer. Moreover, in many applications, flash memory devices comprising transistor devices are needed.

A flash mer nor (for example, a FLASH EPROM or FLASH EEPROM) is a semiconductor device that is formed from an array of memory cells (devices) with each cell having a floating gate transistor. Flash memory chips fall into two main categories, namely, those having a so-called “NOR” architecture and those having a so-called “NAND” architecture. Data may be written to each cell within the array, but the data is erased in blocks of cells. Each floating gate transistor comprises a source, drain, floating gate and control gate. For example, in embedded flash applications, the floating gate uses channel hot electrons for writing from the drain and tunneling for erasure from the source. In the context of NAND memories, Fowler-Nordheim injection is commonly used.

The sources of each floating gate in each cell in a row of the array are connected to form a source line. In embedded memory solutions, memory cells are provided in the neighborhood of logic devices and are, particularly, together with the logic devices on a single (monolithic) silicon substrate. Flash memory devices are used in many applications, including hand held computing devices, wireless telephones and digital cameras, as well as automotive applications. To enable the individual memory elements of a flash memory chip to maintain the physical state with which they have been programmed, each memory region must be isolated from its neighboring regions, typically by shallow trench isolations.

A variety of single gate and split gate solutions for embedded memory cell architectures are known in the art. FIG. 1 illustrates, for exemplary purposes, an embedded super flash cell of the art. The cell is formed on a semiconductor substrate 11 wherein source/drain regions 12 are formed. The cell comprises a floating gate 13, a control gate 14, an erase gate 15 and a select gate 16 formed by a word line. All gates may be made of polysilicon and they are covered by a multilayer insulation structure 17. The multilayer insulation structure 17 comprises parts of spacer structures formed on the tops and sidewalls of the gates. The floating gate 13 is formed over a floating gate oxide layer 18 and it is separated from the erase gate 15 by a tunnel oxide layer 18a that may be formed of the same material as the floating gate oxide layer 18. The control gate 14 and the floating gate 13 are separated from each other by an isolation layer 19, for example, an oxide-nitride-oxide (ONO) layer provided in order to enhance the capacitive coupling between the floating gate 13 and the control gate 14.

However, whereas flash cell integration in the context of manufacturing of field effect transistors (FETs) with silicon-oxynitride gate dielectrics can be reliably achieved, integration of flash cells in CMOS technologies used for the formation of FETs (and, for example, comprising the formation of high-k metal gate transistor devices) still poses challenging problems. Particularly, in the context of Fully Depleted Silicon-On-Insulator (FDSOI) Complementary Metal-Oxide-Semiconductor (CMOS) manufacturing techniques, co-integration of non-volatile memory cells as flash memory cells requires many additional deposition and masking steps, thereby significantly increasing the complexity of the overall processing and manufacturing costs.

In view of the situation described above, the present disclosure provides a technique of forming a semiconductor device comprising a flash memory device integrated within (FD)SOI technologies with a reduced number of processing steps as compared to the art. In addition, a semiconductor device comprising a flash memory device formed according to a method of manufacturing in accordance with the present disclosure is provided.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally the subject matter disclosed herein relates to the manufacturing of a semiconductor device, for example, an FDSOI semiconductor device, comprising a memory device, in particular, a non-volatile flash memory device, and a FET. The FET may be an HKMG FET comprising a FET gate electrode formed over a high-k dielectric layer. The FET gate may comprise a metal material and a polysilicon material formed over the metal material. Due to the particular manufacturing technique disclosed herein, the formation of the memory device can be integrated in the process flow of FDSOI manufacturing.

A method of manufacturing a semiconductor device is provided including the steps of providing a silicon-on-insulator (SOI) substrate, in particular an FDSOI substrate, comprising a semiconductor bulk substrate, a buried oxide layer formed on the semiconductor bulk substrate and a semiconductor layer formed on the buried oxide layer, and forming a memory device on the SOI substrate including forming a floating gate from a part of the semiconductor layer, forming an insulating layer (an interpoly dielectric) on the floating gate, and forming a control gate on the insulating layer.

Formation of the memory device may be integrated in an FDSOI process flow wherein a FET is formed. Particularly, the insulation layer may be formed before formation of a gate electrode of the FET and it may be provided as an oxide-nitride-oxide layer.

Moreover, a method of manufacturing a semiconductor device is provided including the steps of forming a flash memory device on and in an SOI substrate that comprises a semiconductor bulk substrate, a buried oxide layer formed on the semiconductor bulk substrate and a semiconductor layer formed on the buried oxide layer, and forming a transistor device on and in the SOI substrate. Forming the transistor device includes forming a gate electrode over the SOI substrate. Forming the flash memory device includes: (a) forming a floating gate from a part of the semiconductor layer; (b) forming an insulating layer over the semiconductor layer before forming the gate electrode; and (c) forming a control gate on the insulating layer.

Furthermore, a semiconductor device is provided including an (FD)SOI substrate comprising a semiconductor bulk substrate, a buried oxide layer formed on the semiconductor bulk substrate and a semiconductor layer formed on the buried oxide layer, a memory device comprising a floating gate made of a part of the semiconductor layer, an insulating layer (an interpoly dielectric) formed on the floating gate, as well as a control gate that is formed on the insulating layer.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a memory device of the art;

FIG. 2 shows a flow chart of an exemplary processing according to the present disclosure;

FIG. 3 shows details of the process of ONO formation being part of the process flow illustrated in FIG. 2;

FIG. 4 is a plan view that shows a semiconductor device comprising a memory device with a single control gate and a transistor device according to an example of the present disclosure;

FIG. 5 is a plan view that shows a semiconductor device comprising a memory device with a sliced control gate and a transistor device according to an example of the present disclosure;

FIGS. 6a-6b are cross-sectional views of a semiconductor device similar to the semiconductor device shown in FIG. 4; and

FIG. 7 shows a semiconductor device in accordance with another example of the present disclosure wherein electrical connection of a floating gate and a read/write gate of a memory device is made via a first metallization layer.

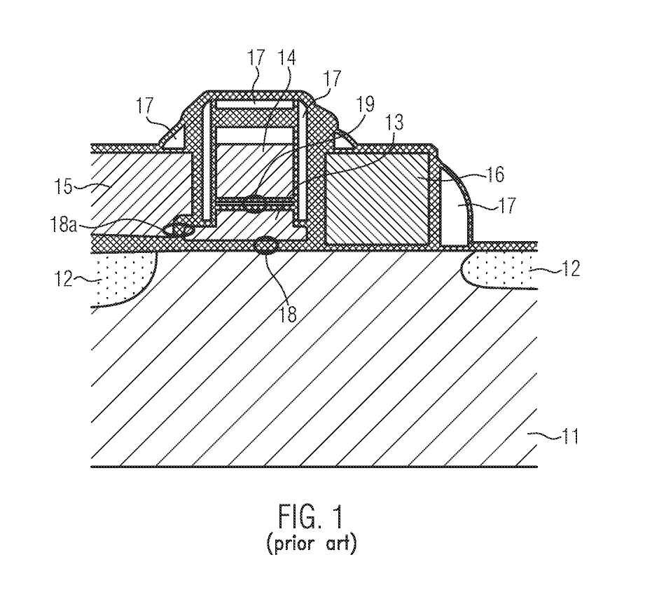

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As used herein, spatial references “top,” “bottom,” “upper,” “lower,” “vertical,” “horizontal” and the like may be used for convenience when referring to structures of semiconductor devices. These references are intended to be used in a manner consistent with the drawings only for teaching purposes, and are not intended as absolute references for semiconductor device structures. For example, FETs or memory devices may be oriented spatially in any manner different from the orientations shown in the drawings. “Vertical” is used to refer to a direction normal to the semiconductor layer surface, and “horizontal” is used to refer to a direction parallel to the semiconductor layer surface when referring to the drawings. “Upper” is used to refer to a vertical direction away from the semiconductor layer. An element positioned “above” (“below”) another one is located farther away from (closer to) the semiconductor layer surface as compared to the other one.

Generally, manufacturing techniques and semiconductor devices in which N-channel transistors and/or P-channel transistors and memory cells may be formed are described herein. The manufacturing techniques may be integrated in CMOS manufacturing processes. As will be readily apparent to those skilled in the art upon a complete reading of the present application, the present method is applicable to a variety of technologies, for example, NMOS, PMOS, CMOS, etc., and is readily applicable to a variety of devices, including, but not limited to, logic devices, memory devices, SRAM devices, etc., in principle. The techniques and technologies described herein may be utilized to fabricate MOS integrated circuit devices, including NMOS integrated circuit devices, PMOS integrated circuit devices, and CMOS integrated circuit devices. In particular, the process steps described herein are utilized in conjunction with any semiconductor device fabrication process that forms gate structures for integrated circuits, including both planar and non-planar integrated circuits. Although the term “MOS” properly refers to a device having a metal gate electrode and an oxide gate insulator, that term is used throughout to refer to any semiconductor device that includes a conductive gate electrode (whether metal or other conductive material) that is positioned over a gate insulator (whether oxide or other insulator) which, in turn, is positioned over a semiconductor substrate.

The present disclosure, generally, provides techniques for the formation of logic devices and memory cells within, for example, (FD)SOI processing. In particular, in one example, a manufacturing technique of a memory device (cell) integrated in the process flow of the formation of a high-k dielectric—poly gate FET or a high-k dielectric—metal-poly gate FET is provided. The memory cell may be or include a flash memory, floating body storage transistor, FLASH EPROM or FLASH EEPROM, etc.

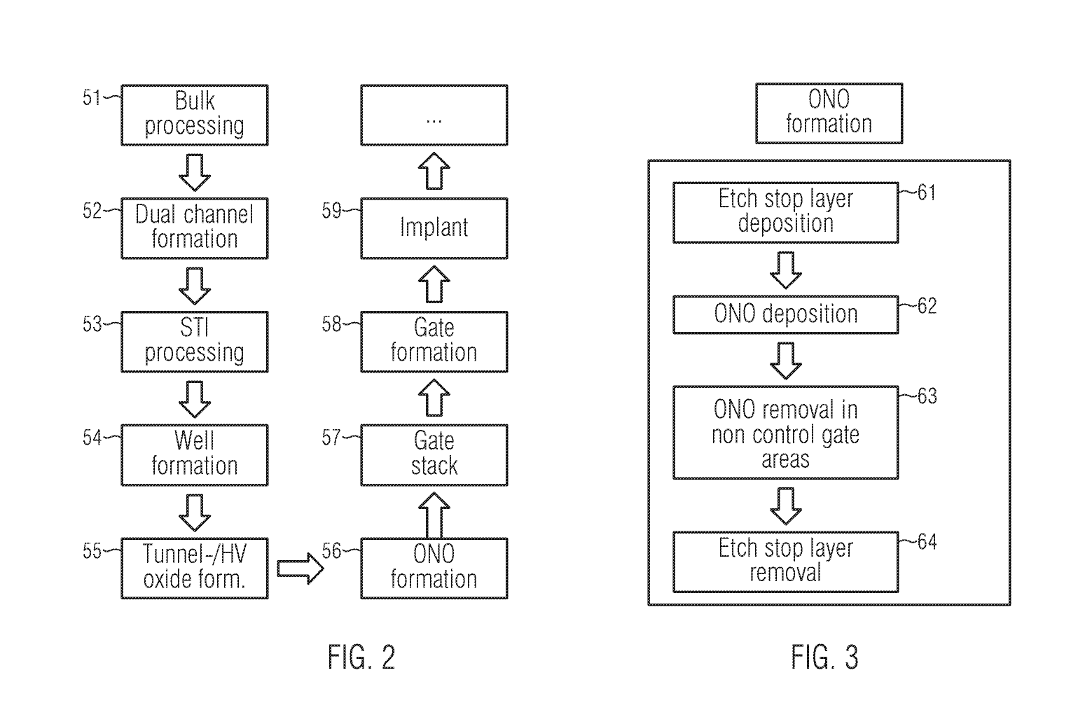

FIG. 2 shows a flow chart of an example of the manufacturing technique provided herein. An SOI (Semiconductor-On-Insulator) substrate is provided by appropriate bulk processing 51. The SOI substrate may comprise a semiconductor bulk substrate, a buried oxide (BOX) layer formed on the semiconductor bulk substrate and a semiconductor layer (or so-called active layer) formed on the BOX layer. The semiconductor layer may comprise a significant amount of silicon due to the fact that semiconductor devices of high integration density may be formed in volume production on the basis of silicon due to the enhanced availability and the well-established process techniques developed over the last decades. However, any other appropriate semiconductor materials may be used, for instance, a silicon-based material containing other iso-electronic components, such as germanium, carbon, silicon/germanium, silicon/carbon, other II-VI or III-V semiconductor compounds and the like.

The BOX layer of the SOI substrate may comprise silicon (di)oxide or a borosilicate glass or a borophosphosilicate glass (BPSG). The BOX layer may be composed of different layers and one of the different layers may comprise BPSG or an SiO₂-compound comprising boron or phosphorus. The semiconductor bulk substrate may comprise or consist of silicon, in particular, single crystal silicon. Other materials may be used to form the semiconductor bulk substrate such as, for example, germanium, silicon germanium, gallium phosphate, gallium arsenide, etc. For example, the thickness of the semiconductor layer may be in the range of 5-30 nm, in particular, 5-15 nm, and the thickness of the BOX layer may be in the range of 10-50 nm, in particular, 10-30 nm and, more particularly, 15-25 nm.

Dual channel formation 52 results in the formation of channel regions of N-channel and P-channel transistor devices. In principle, the dual channel formation may comprise the formation of stressed semiconductor materials, for example, SiGe, on and/or in the SOI substrate, as it is known in the art. An STI-Module is used for STI processing 53 in order to form a plurality of shallow trench isolation (STI) regions. An STI separates an area designated for the formation of a logic device, particularly, a FET, i.e., a logic area, from an area designated for the formation of a memory cell, i.e., a (flash) memory area. The STI regions may be formed by etching openings through the semiconductor layer and the BOX layer of the SOI substrate and in the semiconductor bulk substrate and filling the opening by some insulating material, for example, some oxide material.

Well formation is performed 54 in the semiconductor bulk substrate by appropriate implantation of N-type and P-type dopants. An oxide layer is formed 55 over the SOI substrate. The oxide layer may be formed by thermal oxidation or by an atmospheric or low pressure chemical vapor deposition (LPCVD) process and it may comprise a high-voltage oxide functioning as a gate dielectric and/or a tunnel oxide.

According to the present disclosure, ONO formation is performed 56 before gate stack formation 57. The ONO formation results in the formation of an isolation layer, for example, an oxide-nitride-oxide (ONO) layer, over the SOI substrate that is provided in order to enhance the capacitive coupling between a floating gate and a control gate of a memory device to be formed. Whereas in the following the isolation layer constituting an interpoly dielectric is called an ONO layer, the isolation layer may be made differently, for example, it may be formed of silicon oxynitride or some oxide only.

Some details of the ONO formation 56 are shown in FIG. 3. The ONO formation 56 may comprise deposition of an etch stop layer 61 followed by the deposition of the ONO layer 62 over the SOI substrate. Subsequently, the ONO layer is removed 63 from all regions of the logic area and the memory area with the exception of the region where a control gate of the memory device is to be formed. Removal of the ONO layer is facilitated by the etch stop layer. Subsequently, the etch stop layer is removed 64. However, usage of the etch stop layer is merely optional.

Coming back to the process flow illustrated in FIG. 2, a multilayer gate stack formation is performed 57 after completion of the ONO formation 56. The gate stack formation 57 provides for the formation of a gate electrode of a transistor device in a logic area as well as gates of the memory device in the memory area. In particular, in the logic area, the gate stack formation 57 may comprise the formation of a high-k dielectric layer, for example, with a dielectric constant k>5, k>0 or k>13, that may comprise a transitional metal oxide, such as at least one of hafnium oxide, hafnium dioxide and hafnium silicon-oxynitride. A work function adjusting layer may be formed on the high-k dielectric layer and may comprise titanium nitride (TiN) or any other appropriate work function adjusting metal or metal oxide that is known in the art. The gate stack, furthermore, may comprise a metal gate layer and/or a polysilicon layer. The metal gate layer, for example, comprises a plurality of layers that may include Al, AlN or TiN. In particular, the metal gate layer may comprise a work function adjusting material that comprises an appropriate transition metal nitride, for example, those from groups 4-6 in the periodic table, including, for example, titanium nitride (TiN), tantalum nitride (TaN), titanium aluminum nitride (TiAlN), tantalum aluminum nitride (TaAlN), niobium nitride (NbN), vanadium nitride (VN), tungsten nitride (WN), and the like with a thickness of about 1-60 nm, i.e., the work function adjusting layer may be integrated in the metal gate layer. However, according to a particular design scheme, a pure silicon layer may be formed from which the gate electrode may be obtained by etching.

By appropriate photolithography processing and etching, a gate is formed 58 from the gate stack. Sidewall spacers may be formed at sidewalls of the (logic) gate. The sidewall spacers may include silicon dioxide and/or silicon nitride. The sidewall spacers may be provided in the form of multilayers by subsequently epitaxially growing or depositing the respective layers on the sidewalls of the gate and appropriately etching them.

Some post gate processing 59 including the implantation of dopants and annealing processes to form source/drain regions, source/drain extension regions, etc., may follow. The post gate processing may include the formation of source/drain regions, source/drain extension regions and halo regions in SOI applications. Silicidation of source/drain regions and/or the logic gate and Back-End-of-Line processing may follow.

By means of the process flow illustrated in FIGS. 2 and 3, in particular, a NOR or a NAND memory cell comprising a plurality of memory devices and transistor devices may be formed.

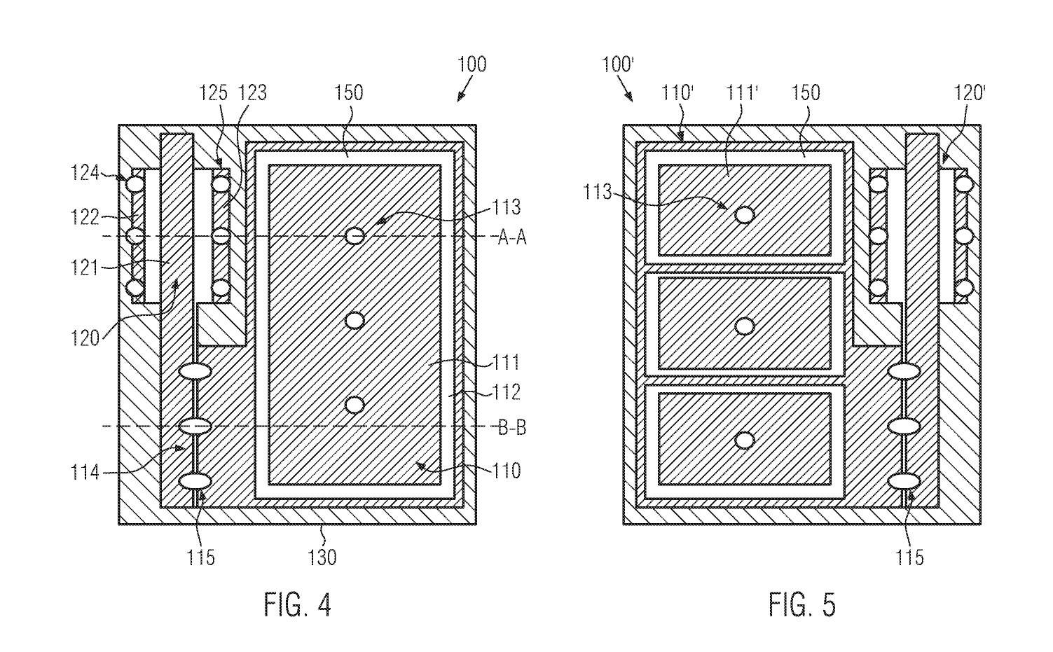

Semiconductor devices that may be formed in accordance with the above-described exemplary process flow are illustrated in FIGS. 4-7. FIGS. 4 and 5 are plan views of two alternative examples of a semiconductor device according to the present disclosure. The semiconductor device 100 shown in FIG. 4 comprises a flash memory device 110 and a FET 120 surrounded by an insulation layer 130 that may be a buried oxide layer of an SOI substrate. In the plan view of FIG. 4, a silicided control gate 111 and part of a floating gate 112 of the memory device 110 are shown. The control gate 111 is contacted to a word line (not shown in FIG. 4) via word line/control electrode contacts 113. The word line/control electrode contacts 113, as well as all other electrical contacts mentioned in the following, are made of a conductive material and may comprise, for example, aluminum or tungsten.

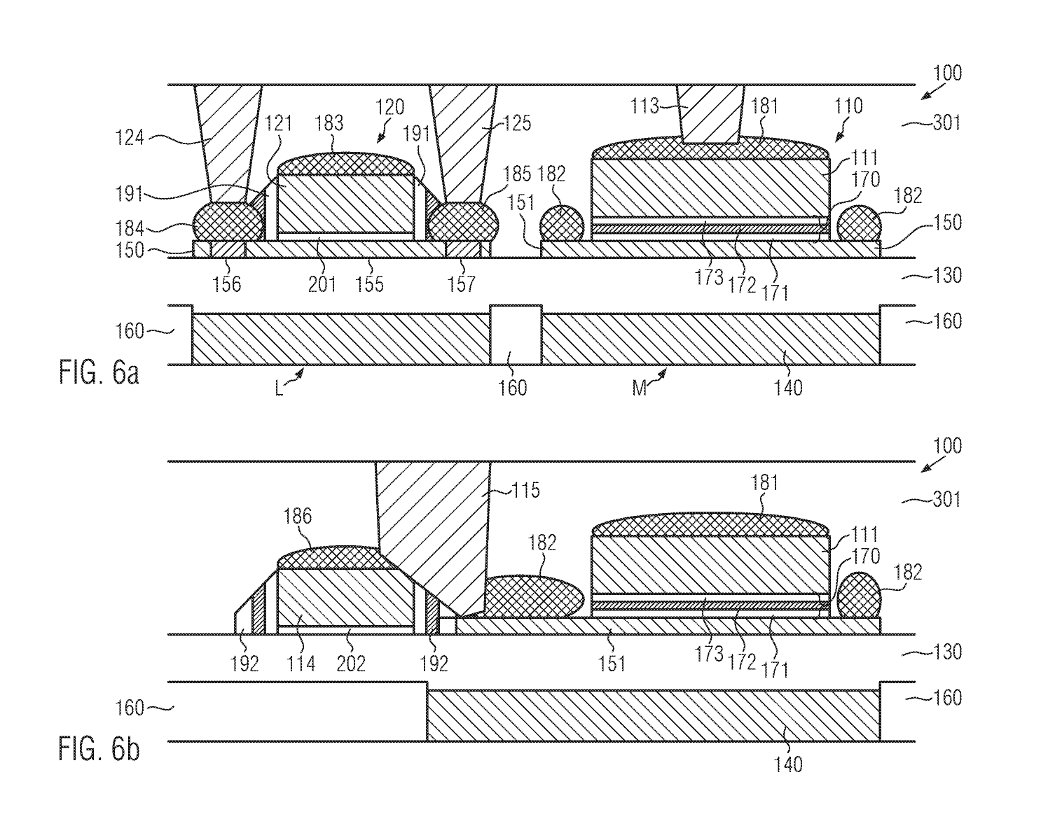

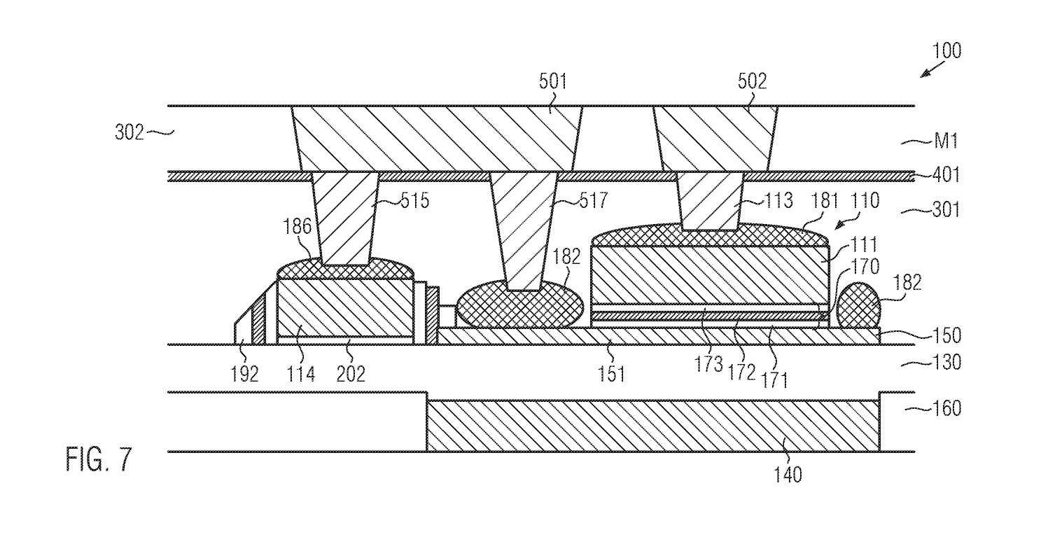

Further, the semiconductor device 100 illustrated in FIG. 4 comprises a silicided read/write gate (erase gate) 114. The read/write gate (erase gate) 114 is electrically contacted to the floating gate 112 via rectangular contacts (Carecs) 115. Moreover, the read/write gate 114 may be formed continuously (integrally) with at least a part of the silicided gate electrode 121 of the transistor device 120. The transistor device 120, furthermore, comprises a silicided source region 122 and a silicided drain region 123. The silicided source region 122 is electrically connected to a source line (not shown in FIG. 4) by source contacts 124 and the silicided drain region 123 is electrically connected to a bit line (not shown in FIG. 4) by source contacts 125. In addition, non-silicided parts of an underlying semiconductor layer 150 are shown in FIG. 4. The semiconductor layer 150 is part of an SOI substrate and formed on a buried oxide layer that is formed on a semiconductor bulk substrate (see also description with reference to FIGS. 6a, 6b and 7 below). It is noted that sidewall spacers (not shown in FIG. 4) may be formed at sidewalls of the silicided gate electrode 121 of the transistor device 120 and the read/write gate 114 of the memory device 110.

FIG. 5 shows a semiconductor device 100′ similar to the one shown in FIG. 4. The semiconductor device 100′ comprises a memory device 110′ and a transistor device 120′. Different from the memory device 110 of the semiconductor device 100 shown in FIG. 4, the memory device 110′ of the semiconductor device 100′ illustrated in FIG. 5 comprises a silicided sliced control gate 111′.

FIGS. 6a and 6b show cross-sectional views of a semiconductor device similar to the one shown in FIG. 4 along the lines A-A and B-B of FIG. 4, respectively. The semiconductor device 100 shown in FIG. 6a comprises a memory area M where a memory device 110 is formed and a logic area L where a transistor device 120 is formed. The semiconductor device 100 is formed on an SOI substrate comprising a semiconductor bulk substrate 140, a buried oxide (BOX) layer 130 and a semiconductor layer 150.

The semiconductor bulk substrate 140 may comprise or consist of silicon, in particular, single crystal silicon. Other materials may be used to form the semiconductor bulk substrate such as, for example, germanium, silicon germanium, gallium phosphate, gallium arsenide, etc. The BOX layer 130 may comprise BPSG or an SiO₂-compound comprising boron or phosphorus. The semiconductor layer 150 may comprise or consist of silicon, in particular, crystalline silicon. Moreover, STI regions 160 for electrical insulation are formed by etching openings through the semiconductor layer 150 and the BOX layer 130 of the SOI substrate and in the semiconductor bulk substrate 140 and filling the opening by some insulating material, for example, some oxide material. It is noted that the semiconductor bulk substrate 140 may be used as a back gate in both the memory device 110 and the transistor device 120.

A portion of the semiconductor layer 150 that is formed in the memory area M represents/provides a floating gate 151 of the memory device 110. In the logic area L, the semiconductor layer 150 provides a channel region 155 of the transistor device 120. In the memory area M, an ONO layer 170 is formed on the semiconductor layer 150 (the floating gate layer 151). The ONO layer 170 consists of a first oxide layer 171, a nitride layer 172 and a second oxide layer 173. As already described with reference to the process flow illustrated in FIGS. 2 and 3, the ONO layer 170, according to the present disclosure, is formed before the formation of the gate electrode 121 of the transistor device 120. A control gate 111, for example, comprising or consisting of polysilicon, is formed on the ONO layer 170. A silicide layer 181 is formed on the upper surface of the control gate 111. Additionally, silicided regions 182 are formed on the floating gate 151. The control gate 111 is contacted to a word line (not shown in FIG. 6a) via a word line/control gate contact 113.

The transistor device 120 of the semiconductor device 100 shown in FIG. 6a comprises a gate dielectric 201 over which the silicided gate electrode 121 is formed. The gate electrode 121 may comprise multiple layers of metal and/or (poly)silicon material. According to an example, the gate electrode 121 is made of crystalline silicon. On the upper surface of the gate electrode 121, a silicide layer 183 is formed. The transistor device 120 comprises a source region 156 and a drain region 157, both formed by appropriate doping of the semiconductor layer 150. The source region 156 and the drain region 157 are silicided by silicide layers 184 and 185, respectively. The source region 156 is contacted to a source line (not shown in FIG. 6a) via contact 124 and the drain region 157 is contacted to a bit line (not shown in FIG. 6a) via contact 125.

In FIG. 6b, a memory area of the semiconductor device 100 is shown in a cross-sectional view taken along the line B-B of FIG. 4. FIG. 6b shows the silicided read/write gate 114 comprising, for example, (poly)silicon. In the shown example, the read/write gate 114 is formed on a dielectric layer 202 that is directly formed on the BOX layer 130 after removal of the corresponding portion of the semiconductor layer 150 of the SOI substrate. A silicide layer 186 is formed on an upper surface of the read/write gate 114. Moreover, FIG. 6b shows a rectangular contact 115 provided for electrically connecting the read/write gate 114 and the floating gate 151.

FIGS. 6a and 6b also show sidewall spacers 191 and 192 formed on sidewalls of the gate electrode 121 and the read/write gate 114, respectively, that are not shown in FIG. 4. It is noted that, depending on the actual process flow, sidewall spacers may also be formed on sidewalls of the control gate 111 of the memory device 110. Further, the semiconductor device 100 shown in FIGS. 6a and 6b comprises an interlayer dielectric 301. The interlayer dielectric 301 may be made of an oxide material and it may comprise silicon dioxide. The respective contacts 113, 115, 124, 125 are formed in the interlayer dielectric 301. All or some of the silicide regions shown in FIGS. 6a and 6b may comprise or consist of nickel silicide, for example.

In FIG. 7, a semiconductor device 100 similar to the one shown in FIG. 6b is illustrated. The difference to the semiconductor device 100 of FIG. 6b basically relates to the realization of the electrical contacting of the read/write gate 114 of the memory device 110 to the floating gate 151 of the memory device 110. The semiconductor device 100 shown in FIG. 7 comprises a first metallization layer M1 separated from the interlayer dielectric 301 by some insulation layer 401.

Metal structures 501 and 502 are formed in another interlayer dielectric 302. The other interlayer dielectric 302 may be made of an oxide material and it may comprise silicon dioxide. The metal structure 502 may represent a word line that is connected to the control gate 111 of the memory device 110 via the word line contact 113. The metal structure 501 provides for electrically contacting the read/write gate 114 of the memory device 110 to the floating gate 151 of the same via contacts 515 and 517 formed in the interlayer dielectric 301.

As a result, the present disclosure provides techniques for the integration of the formation of a memory device, in particular, a flash memory device, in the (FD)SOI manufacturing process flow of FETs. The memory device may be part of a NOR or NAND flash memory cell. Thereby, the (FD)SOI manufacturing of reliably operating semiconductor devices comprising memory cells and logic devices may be significantly improved as compared to the art, since the number of additional deposition and masking steps needed for the formation of the memory device is significantly reduced. Particularly, the memory device may comprise a semiconductor layer of an (FD)SOI substrate as a floating gate.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method of manufacturing a semiconductor device, comprising:
providing a silicon-on-insulator (SOI) substrate comprising a semiconductor bulk substrate, a buried oxide layer formed on said semiconductor bulk substrate and a semiconductor layer formed on said buried oxide layer; and
forming a memory device on said SOI substrate comprising forming a floating gate from a part of said semiconductor layer, forming an insulating layer on said floating gate and forming a control gate on said insulating layer.

2. The method of claim 1, wherein said insulating layer is an oxide-nitride-oxide layer.

3. The method of claim 1, further comprising forming a transistor device comprising forming a gate electrode, wherein said gate electrode is formed after formation of said insulating layer.

4. The method of claim 3, wherein forming said memory device further comprises forming a read/write gate and wherein said gate electrode of said transistor device is formed at least partly integrally with said read/write gate.

5. The method of claim 1, wherein forming said memory device further comprises forming a read/write gate, the method further comprising:
forming an interlayer dielectric over said control gate and said read/write gate; and
electrically connecting said floating gate and said read/write gate by a contact that is formed in said interlayer dielectric and directly contacts said floating gate and said read/write gate.

6. The method of claim 1, wherein forming said memory device further comprises forming a read/write gate and further comprising:
forming an interlayer dielectric over said control gate and said read/write gate;
forming a first metallization layer over said interlayer dielectric;
forming a metallization structure in said first metallization layer;
forming a first contact in said interlayer dielectric contacting said metallization structure and said read/write gate; and
forming a second contact in said interlayer dielectric contacting said metallization structure and said floating gate.

7. The method of claim 1, wherein forming said memory device further comprises forming a back gate in said semiconductor bulk substrate.

8. A method of manufacturing a semiconductor device, comprising:
forming a flash memory device on and in an silicon-on-insulator (SOI) substrate that comprises a semiconductor bulk substrate, a buried oxide layer formed on said semiconductor bulk substrate and a semiconductor layer formed on said buried oxide layer; and
forming a transistor device on and in said SOI substrate;
and wherein:
forming said transistor device comprises forming a gate electrode over said SOI device; and
forming said flash memory device comprises (a) forming a floating gate from a part of said semiconductor layer, (b) forming an insulating layer over said semiconductor layer before forming said gate electrode and (c) forming a control gate on said insulating layer.

9. The method of claim 8, wherein forming said memory device comprises forming a read/write gate over said SOI substrate and wherein said gate electrode of said transistor device is at least partly formed of the same layer as said read/write gate.

10. The method of claim 8, wherein said insulating layer is an oxide-nitride-oxide layer.

11. The method of claim 8, wherein forming said memory device comprises forming a read/write gate over said SOI substrate and further comprising forming an interlayer dielectric over said control gate and said read/write gate and electrically connecting said floating gate and said read/write gate by a contact that is formed in said interlayer dielectric and directly contacts said floating gate and said read/write gate.

12. The method of claim 8, wherein forming said memory device further comprises forming a read/write gate and further comprising:
forming an interlayer dielectric over said control gate and said read/write gate;
forming a first metallization layer over said interlayer dielectric;
forming a metallization structure in said first metallization layer;
forming a first contact in said interlayer dielectric contacting said metallization structure and said read/write gate; and
forming a second contact in said interlayer dielectric contacting said metallization structure and said floating gate.

13. The method of claim 12, further comprising forming a word line in said first metallization layer and contacting said word line to said control gate via a contact formed in said interlayer dielectric.

14. The method of claim 8, wherein forming said memory device further comprises:
removing a part of said semiconductor layer to provide an exposed part of said buried oxide layer;
forming a dielectric layer on said exposed part of said buried oxide layer; and
forming a read/write gate on said dielectric layer.

15. The method of claim 8, wherein forming said transistor device further comprises forming a high-k dielectric layer between said gate electrode and said semiconductor layer.

16. A semiconductor device, comprising:
a silicon-on-insulator (SOI) substrate comprising a semiconductor bulk substrate, a buried oxide layer formed on said semiconductor bulk substrate and a semiconductor layer formed on said buried oxide layer;
a memory device comprising a floating gate made of a part of said semiconductor layer;
an insulating layer formed on said floating gate; and
a control gate formed on said insulating layer.

17. The semiconductor device of claim 16, further comprising a field effect transistor comprising a channel region that is made of another part of said semiconductor layer and electrically insulated from said floating gate.

18. The semiconductor device of claim 16, wherein said memory device further comprises a read/write gate electrically connected to said floating gate.
